(19) United States
(12) Patent Application Publication
(10) Pub. No.: US 2004/0196083 A1
(43) Pub. Date: Oct. 7, 2004

(54) System and method for generating balanced signals with arbitrary amplitude and phase control using modulation

(76) Inventor: Joel P. Dunsmore, Sebastopol, CA (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/405,556

(22) Filed: Apr. 2, 2003

(51) Int. Cl. H03K 3/00

(52) U.S. Cl. 327/231

(57) ABSTRACT

Differential (balanced) drive signals are created where at least one of the drive signals can be controlled in phase relative to the other, and both of which could be controlled in amplitude. In one embodiment, a coherent signal is generated in a first electronic signal generator (ESG) and applied to a second ESG. The coherent signal replaces the normal input signal of the second ESG and the I and Q inputs of the second ESG controls the amplitude and phase of the output signal. This output signal, when combined with the output signal of the first ESG is a differentially balanced signal having both amplitude and phase control.

### CROSS-REFERENCE TO RELATED APPLICATIONS

The present application is related to concurrently filed, co-pending, and commonly assigned U.S. patent application Ser. No. ______, Attorney Docket No. 10030022-1, entitled “SYSTEM AND METHOD FOR GENERATING BALANCED MODULATED SIGNALS WITH ARBITRARY AMPLITUDE AND PHASE CONTROL USING MODULATION”; and U.S. patent application Ser. No. ______, Attorney Docket No. 10030042-1, entitled “SYSTEM AND METHOD FOR CALIBRATING BALANCED SIGNALS”, the disclosures of which are hereby incorporated herein by reference.

### TECHNICAL FIELD

This invention relates to balanced differential output generation circuits and more particularly to systems and methods for generating balanced signals with arbitrary amplitude and phase control using modulation.

### BACKGROUND OF THE INVENTION

Advances in technology have allowed for smaller, lower power devices. Many of these device topologies now use balanced (or differential) input drives instead of the traditional single-ended inputs and outputs. Thus, a two-port balanced device would have four single-ended connections, input+ and input−, and output+ and output−. It is known that for passive devices, or active devices operating in their linear region, it is sufficient to measure the individual single-ended responses from a balanced device, and combine the results mathematically to obtain the differential or balanced response. For this to work correctly, the device must behave linearly, which means the signals are small enough such that the device behavior does not change with signal level.

However, many devices are not linear throughout their range of operation. For example, an amplifier might change its bias current between large signals and small signals. For such devices, it is necessary to drive them with real-time signals that present the proper amplitude and phase relationships. These drive signals must be presented at the input ports (+ and −) of the device under test (DUT) with the same amplitude and 180° of phase difference, to be a true differential signal.

For some applications, a balun (balanced to unbalanced transformer) is often used, and is placed in close proximity to the device to avoid introducing any phase offset due to connections between the device and the balun. In test equipment applications, however, it may not be possible to control the interconnections sufficiently well to maintain desired balance. Further, the signaling used in many devices is of a complex modulation form and has substantial bandwidth. Baluns may distort the measurement over this substantial bandwidth. Circuits known for producing balanced outputs include Baluns and hybrids, such as 3-dB directional couplers, all of which are limited in that the phase of the output is fixed, and cannot be adjusted to compensate for different line lengths to the DUT, or unwanted imbalance in the Balun or hybrid.

### BRIEF SUMMARY

Differential (balanced) drive signals are created where at least one of the drive signals can be controlled in phase and amplitude relative to the other. For more general application, it is preferable if both drive signals can be controlled in amplitude. In one embodiment, a coherent signal is generated in a first electronic signal generator (ESG) and applied to a second ESG. The coherent signal replaces the normal input signal of the second ESG and the I and Q inputs of the second ESG controls the amplitude and phase of the output signal. This output signal, when combined with the output signal of the first ESG is a differentially balanced signal having both amplitude and phase control.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood front the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 is a block diagram showing one embodiment of a system and method for providing a differential output;

FIGS. 2 and 3 are graphs showing output characteristics of the circuit of FIG. 1;

FIG. 4 is one embodiment of a testing system using the concepts of the disclosure;

FIG. 5 shows one alternate system arrangement; and

FIG. 6 shows one embodiment of differential balanced network analyzer system.

### DETAILED DESCRIPTION OF THE INVENTION

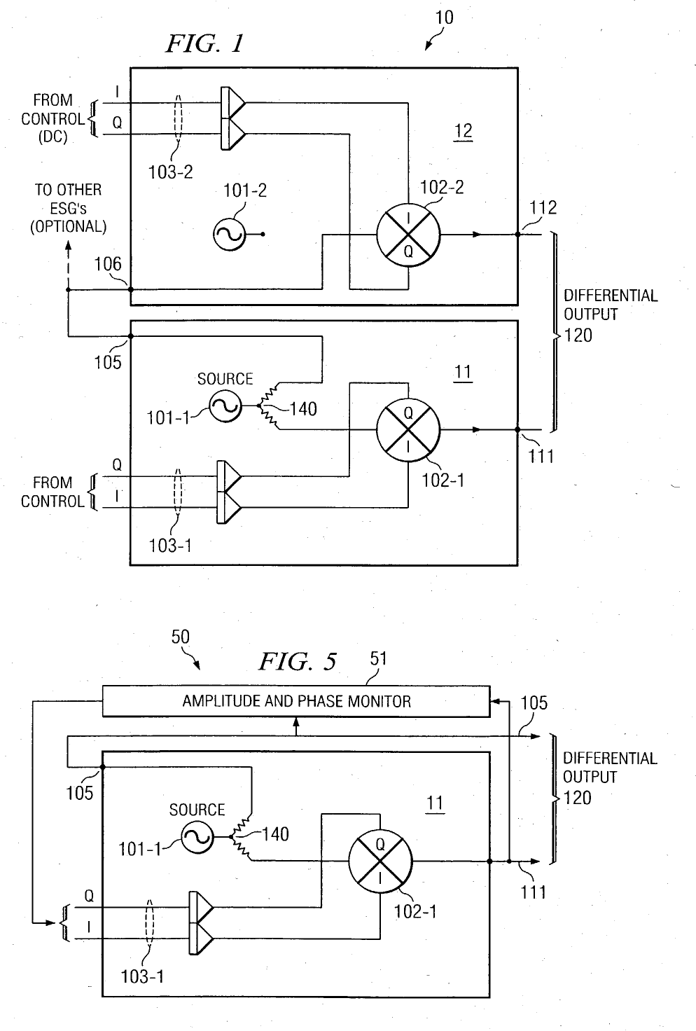

FIG. 1 shows system 10 having electronic signal generators (ESG) 11 and 12, each of which provide complex signals using a vector modulator and an arbitrary waveform generator. ESGs 11 and 12 are available as Agilent Part Number E4438B, or equivalent. The signal source is created by synthesizer 101-1 which produces a continuous wave (CW) frequency signal. This signal is split, using splitter 140, a portion of the signal is routed to node 105 and portion of this same signal is also routed to vector modulator 102-1. The portion of the signal going to node 105 is referred to as the coherent carrier.

Vector modulator 102-1, under direction of I and Q inputs 103-1, controls the amplitude and phase of the output signal which is present on node 111 of ESG 11. This output signal is phase coherent with the signal on node 105.

In one implementation, the node 105 signal is routed to node 106 of ESG 12. ESG 12 is a modified version of ESG 11, where internal synthesizer 101-2 has been bypassed to allow an external signal to be applied to connect node 106 to vector modulator 102-2 of ESG 12. This allows the coherent carrier signal on node 106 from ESG 11 to be applied to vector modulator 102-2 of ESG 12. I and Q inputs 103-2, which advantageously are controllable DC inputs (but could be any type of input, including phase controlled inputs), selectively control vector modulator 102-2 thereby controlling the signal amplitude or phase of the coherent carrier as it is presented to node 112. Thus, node 112 has on it a signal which is both amplitude and phase adjusted and which is phase coherent relative to the signal on node 111. Accordingly, differential output 120 contains signals which are differentially balanced and which are amplitude and phase controlled relative to each other.

In this implementation, first vector modulator 11, second vector modulator 12, or both, may be used to change the amplitude and phase relationship between the signals on nodes 111 and 112. This system allows any arbitrary amplitude and phase of the two outputs to be set, and thus has many applications such as load pull and “smart” antenna test.

FIG. 5 shows the situation where, if amplitude control is not required, it is possible to create a balanced output by pairing coherent carrier 105 of ESG 11 with the main output on node 111. Circuit 50 is arranged such that the I and Q inputs 103-1 are set under control of monitor 51 such that main output 111 has the same amplitude as the coherent carrier (which is not controlled) and has 180° of phase shift from the coherent carrier (which is also not phase controlled). Monitor 51 compares the amplitude and phase of source 101-1 against the amplitude and phase at node 111 and adjusts the I and Q inputs to reduce the error. The relative phase and amplitudes may be measured on test systems, such as vector network analyzers as discussed in co-pending application entitled, “SYSTEM AND METHOD FOR CALIBRATING BALANCED SIGNALS”.

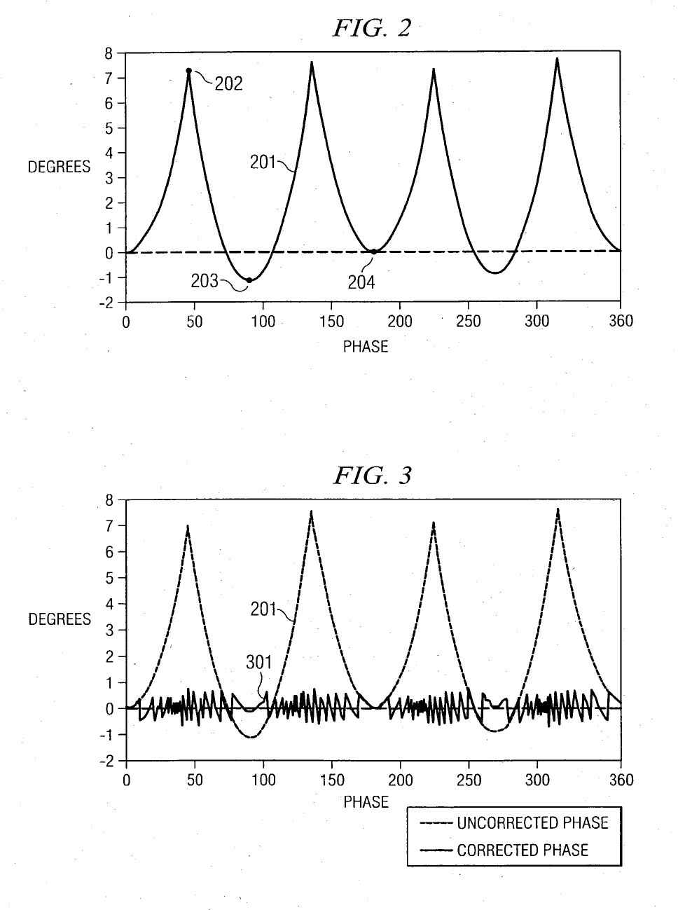

FIG. 2 shows the phase (graph 201) of output 111 compared to output 112, as a function of the desired phase setting. Thus, at a phase setting of 45° (point 202), the phase difference between signals 111 and 112 is slightly over 7°, while at a phase setting of 90° (point 203) the phase difference is 1° in the opposite direction. At approximately 180° (point 204) the signals are in phase. This demonstrates that the phase outputs are not necessarily linear.

When these signals are used for a calibration process (for example, a calibration lookup table), the phase can be corrected so that any arbitrarily small phase error is obtainable. One method of achieving such calibration is shown in co-pending U.S. patent application Ser. No. ______, Attorney Docket No. 10030042-1, entitled “SYSTEM AND METHOD FOR CALIBRATING BALANCED SIGNALS”, filed concurrently herewith.

FIG. 3 shows the result of correcting the phase, where the phase correction resolution is 1°. The original phase relationship is shown as 201. As expected, the resulting phase output 301 is corrected to less than 1° (½° on either side of zero).

There are many applications where having two (or more) phase coherent sources, whose phase and amplitude are variable, can be useful in solving problems. One such application is load-pull, where it is desired to create an output reflection coefficient of a particular value, when a device (typically an amplifier) is driven at some level. This is particularly important when the device is driven at a level causing non-linear behavior. Having the capability of changing the magnitude and phase of the reflection, coherent with the drive signal, allows for the creation of an apparent constant load to the device under test regardless of the signal phase relationship.

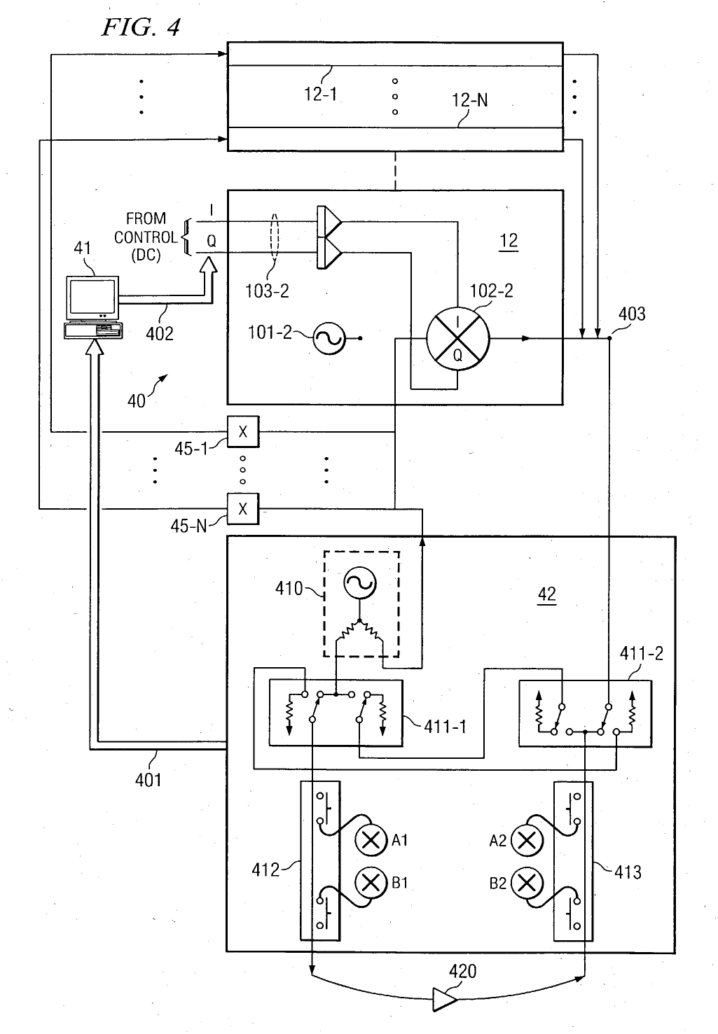

FIG. 4 shows block diagram system 40 which allows for matching the phase and magnitude for testing purposes. Computer 41 reads the output signal, via taps 412 and 413 (measured at B2/A1), and creates a corresponding signal (measured at A2/A1) with the amplitude and phase as to produce the proper reflected signal to the amplifier.

As shown in FIG. 4, test set 42 applies a signal from source 410 through switch 411-1 to device under test, such as device 420. A coherent portion of the signal from source 410 is applied to vector modulator 103-2, as discussed above with respect to FIG. 1. Computer 41 reads the signal through device 420 at terminal B2 and also reads the input signal at terminal A1. Computer 41 then adjusts the DC I and Q inputs 103-2 to modulator 102-2, thereby adjusting the phase and, if necessary, the amplitude of the signal at node 403. The signal at node 403 is applied, via switch 411-2, as a reflected load signal to device 420. Calibrations can be made on such a system, allowing automatic routines to calculate and set the proper phase and amplitude of the signals on node 403. An example of such calibration is shown in co-pending U.S. patent application Ser. No. ______, Attorney Docket No. 10030042-1, entitled “SYSTEM AND METHOD FOR CALIBRATING BALANCED SIGNALS”. It should be recognized that this method can be extended to harmonic load pull, by adding a frequency multiplier, such as multiplier 45-1, between source 410 and modulator 102-2. This signal may be split as necessary to be applied to any number of multipliers 45-N, the outputs of which may be applied to the same number of vector modulators 12-1 to 12-N. The outputs of the vector modulators may be combined with node 403 to produce a harmonic load pull system, with an arbitrary number of harmonics. Each multiplier is chosen to select a desired harmonic.

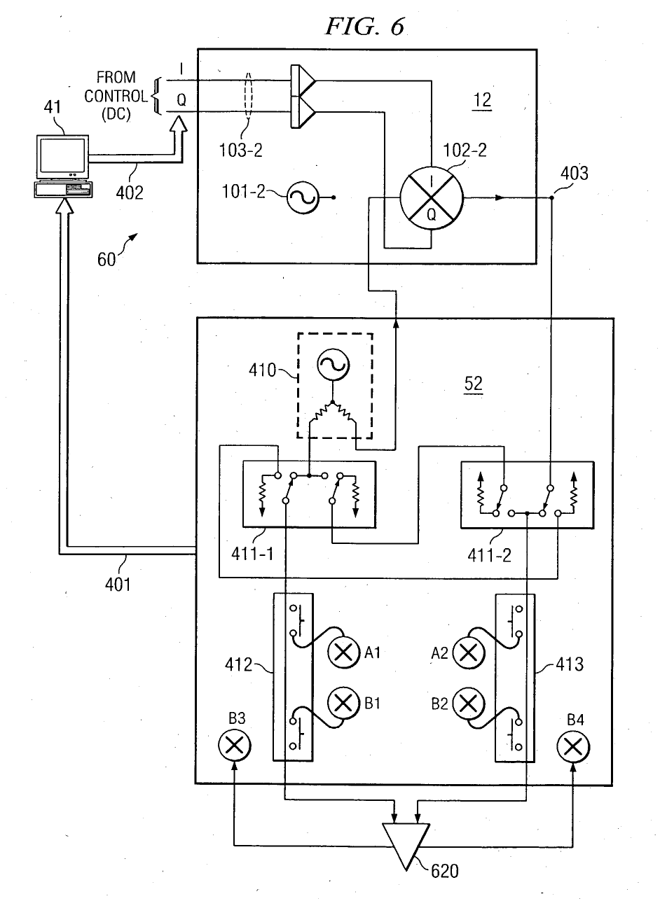

FIG. 6 shows one embodiment of differential balanced analyzer system 60 where the balanced signals at A1 and A2 go to the dual inputs of DUT 620 and the outputs form DUT 620 are viewed by analyzer 41 via test terminals B3 and B4. Note that switches, or duplicate sources, can be provided so that the signals to DUT 620 can be reversed and measured at terminals B1 and B2 instead of at B3 and B4.

Note that while ESGs 11 and 12 are shown as individual circuits, they could be combined into one circuit, and other circuits could be used in place of one or both ESGs, if desired. Also, the input signal from signal source 101-1 could be provided by an external source.

One advantage of this configuration is that the phase relationship between the outputs, for example, as shown in FIG. 1, is not dependent on the phase of the internal source. As such, the source can be set to a multiple of input frequencies, and the relationship measured for each frequency. A correction array can be created such that the balanced output (or other desired phase relationship) can be achieved over any frequency range of the source. This, in general, is not true of multiple signal generators locked to a common reference, where changing the source frequency does not produce a predictable and repeatable phase relationship at the outputs.

While vector modulators have been shown, other circuitry could be used. For example, amplitude could be controlled by pin diode modulators, step attenuators, voltage variable amplifiers, GaAs FET attenuators, vector modulators, or the like. Phase could be controlled by line stretchers, pin modulators, vector modulators, and phase shifters, or the like.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods, and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A dual output RF signal source comprising:
a first circuit for controlling the amplitude and phase of a first output signal, said first output signal being a modification of an input signal;
a second circuit for providing a second output signal phase coherent with said first output signal; and
circuitry for adjusting the phase and amplitude of one said output signals in relationship to the other of said output signals so as to establish a controllable RF differential output.

2. The dual output signal source of claim 1 wherein said second output signal is said phase coherent signal unmodified and where said phase and amplitude adjusting includes adjusting the phase and amplitude of said first output, such that said amplitude of said first output signal matches said second output signal and such that the phase is shifted by 180°.

3. The dual output signal source of claim 1 wherein second output signal has its amplitude separately adjustable from the amplitude of said first output signal.

4. The dual output signal source of claim 1 wherein said second output signal has its phase and amplitude separately adjustable from the phase and amplitude of said first output signal.

5. The dual output signal source of claim 4 wherein said phase and amplitude of said first and second output signals are controlled by vector modulators having I and Q inputs.

6. The dual output signal source of claim 5 wherein the I and Q inputs to the vector modulator controlling said second output signal is a controllable DC signal.

7. The dual output signal source of claim 1 wherein said first circuit is an electronic signal generator having I and Q inputs for controlling a continuous wave (CW) input signal.

8. The dual output signal source of claim 7 wherein said second circuit is an electronic signal generator having I and Q inputs for controlling said phase coherent signal from said first circuit.

9. The dual output signal source of claim 8 wherein said second circuit I and Q inputs are controllable DC inputs.

10. The dual output signal source of claim 9 wherein said first circuit I and Q inputs are continuous wave (CW) inputs.

11. A circuit for providing a plurality of output signals, said circuit comprising:
first and second electronic signal generators (ESG), each having I and Q inputs, and at least the first ESG having a source of continuous wave (CW) frequency signals with a plurality of CW outputs;
means, including said I and Q inputs of said first ESG, for controlling the amplitude and phase of an output signal of said first ESG, said output signal being a modification of a first portion of one of said CW output signals from said one of the ESG sources; and
means, including said I and Q inputs of said second ESG for controlling the phase of an output signal from said second ESG, said output signal being a modification of a second portion of said CW signal from said first ESG source.

12. The circuit of claim 11 wherein said second portion CW signal from said first ESG is coherent with said first portion CW signal from said first ESG.

13. Circuitry for providing balanced output signals; said circuitry comprising:
a signal source for providing a continuous wave (CW) input signal and an output signal coherent with said CW input signal;
a first modulator for accepting said CW input signal, and under control of I and Q inputs, controlling the amplitude and phase of a modulated first output signal; and
a second modulator for accepting said coherent output signal and under control of I and Q inputs, controlling the phase of a modulated second output signal, said first and second modulated output signals forming a balanced differential pair.

14. The circuitry of claim 13 wherein said first modulator is within a first electronic signal generator (ESG) having a first signal source and a first vector modulator and wherein said second modulator is within a second ESG having a second signal source and a second vector modulator, and wherein a portion of said first signal source is provided to said second vector modulator instead of the signals from said second signal source.

15. Circuitry for device testing where it is desired to apply to said device a second signal having an amplitude and phase in relationship to a first signal being applied to said device, said circuitry comprising:
a first circuit for controlling the amplitude and phase of a first output signal, said first output signal being a modification of an input signal;
a second circuit for providing a second output signal phase coherent with said first output signal; and
circuitry for adjusting the phase and amplitude of one said output signals in relationship to the other of said output signals.

16. The circuitry of claim 15 wherein said second output signal is said phase coherent signal unmodified and where said phase and amplitude adjusting includes adjusting the phase and amplitude of said first output, such that said amplitude of said first output signal matches said second output signal and such that the phase is shifted in a specific relationship with said second signal.

17. The circuitry of claim 16 wherein said first circuit is an electronic signal generator (ESG) having as its input signal said phase coherent signal.

18. The method of providing a differential signal, said method comprising:
controlling the amplitude and phase of a first output signal, said first output signal being a modification of an input signal;
providing a second output signal phase coherent with said first output signal; and
adjusting the phase and amplitude of one of said output signals in relationship to the other of said output signals.

19. The method of claim 18 wherein said second output signal is said phase coherent signal unmodified and where said phase and amplitude adjusting step includes adjusting the phase and amplitude of said first output, such that said amplitude of said first output signal matches said second output signal and such that the phase is shifted by 180°.

20. A method of providing balanced output signals; said method comprising:
providing a continuous wave (CW) input signal and an output signal coherent with said CW input signal;
accepting said CW input signal, and under control of I and Q inputs, controlling the amplitude and phase of a modulated first output signal; and
accepting said coherent output signal and under control of I and Q inputs, controlling the amplitude and phase of a modulated second output signal, said first and second modulated output signals forming a balanced differential pair.

21. The method of claim 20 wherein said CW accepting step is performed within a first electronic signal generator (ESG) having a first signal source and a first vector modulator and wherein said coherent accepting step is performed within a second ESG having a second signal source and a second vector modulator, and wherein a portion of said first signal source is provided to said second vector modulator instead of the signals from said second signal source.

22. A circuit for providing a plurality of output signals, said circuit comprising:
a first modulation circuit having I and Q inputs having a source of continuous wave (CW) frequency signals as a signal input;
a second modulation circuit having I and Q inputs and having a signal input;
means, including said I and Q inputs of said first electronic signal generator (ESG), for controlling the amplitude and phase of an output signal of said first ESG, said output signal being a modification of a first portion of said CW signal; and
means, including said I and Q inputs of said second modulation circuit, for controlling the phase of an output signal from said second modulation circuit, said output signal being a modification of a second portion of said CW signal from said first modulation circuit applied to said signal input of said second modulation circuit, whereas said first ESG output and said second modulation circuit provide said plurality of output signals.

23. The circuit of claim 22 wherein said CW signals are neither phase nor amplitude controlled.

24. The circuit of claim 22 wherein said first modulation circuit controlling means includes a splitter for providing a signal to said second modulator that is coherent with said output signal of said first modulation circuit.

25. A differential balanced analyzer system comprising:
a test source for applying a first signal having a frequency and amplitude to a first input of a device under test (DUT);
a first circuit for accepting as an input, a portion of said first signal and for generating a second signal to a second input of said DUT, said first circuit comprising circuitry for matching the phase and amplitude of said second signal to that of said first signal; and
circuitry for monitoring the output of said DUT.

26. The system of claim 25 wherein said monitoring circuitry provides I and Q control signals for adjusting the phase of said second signal in accordance with said monitored output of said DUT.

27. The system of claim 26 wherein said first circuit comprises a vector modulator for receiving said input and wherein said I and Q control signals modify the output of said vector modulator.

28. The system of claim 27 wherein said I and Q control signals are controllable DC signals.

29. A method for performing a load pull test, said method comprising:
establishing a continuous wave (CW) source signal with at least two outputs;
applying one of said outputs as a driving signal to a device under test (DUT);
accepting in an I and Q modulator the other of said outputs, said modulator having an amplitude and phase controlled output signal; and
applying said amplitude and phase controlled output signal to an output of said DUT.

30. A method for harmonic load pull testing, said method comprising:
establishing a continuous wave (CW) signal source with at least two outputs;
applying one of said outputs as a driving signal to a device under test (DUT);
frequency multiplying the other of said outputs to provide both frequency multiplied as well as non-multiplied signals;
accepting at the input of I and Q modulators both said frequency multiplied and non-multiplied signals; and
applying the combined outputs from said modulators to the output of said DUT.
